(19) United States
(12) Patent Application Publication
(10) Pub. No.: US 2022/0283217 A1
(43) Pub. Date: Sep. 8, 2022

(54) EQUIPMENT SENSING CIRCUIT BOARD AND OPERATION METHOD THEREOF

(71) Applicant: UNITED MICROELECTRONICS CORP., Hsinchu (TW)

(72) Inventors: Ji-Fu KUNG, Taichung City (TW); Yi-Lin HUNG, Tainan City (TW); Chih-Chung KUO, Tainan City (TW); Wei-Che LIN, Tainan City (TW)

(21) Appl. No.: 17/226,460

(22) Filed: Apr. 9, 2021

(30) Foreign Application Priority Data
Mar. 8, 2021 (CN) 202110249178.X

(51) Int. Cl. G01R 31/26

(52) U.S. Cl. CPC G01R 31/2607

(57) ABSTRACT

An equipment sensing circuit board and an operation method thereof are provided. The equipment sensing circuit board equipped on a semiconductor equipment includes a main sensor, a backup sensor, a first electronic fuse, a second electronic fuse, and a multiplexer. The main sensor and the backup sensor are used to monitor the operation of the semiconductor equipment to output a main sensing signal and a backup sensing signal respectively. The first electronic fuse is disposed on the main sensor to output a first status signal. The second electronic fuse is disposed on the backup sensor to output a second status signal. The multiplexer is connected to the main sensor, the backup sensor, the first electronic fuse and the second electronic fuse. The multiplexer selects to output the main sensing signal or the backup sensing signal according to the combination of the first state signal and the second state signal.

This application claims the benefit of People's Republic of China application Serial No. 202110249178.X, filed Mar. 8, 2021, the disclosure of which is incorporated by reference herein in its entirety.

### TECHNICAL FIELD

The disclosure relates in general to a circuit board and an operation method thereof, and more particularly to an equipment sensing circuit board and an operation method thereof.

### BACKGROUND

Semiconductor technology has moved towards the Industry 4.0 generation. In the Industry 4.0 generation, semiconductor equipment can perform Prognostic and Health Management (PHM) through sensors to predict whether the production line is abnormal and needs to be adjusted. By precision monitoring can avoid a large number of defective products in the final product.

In addition, the information of the sensor can also assist in Virtual Metrology (VM). Virtual Metrology can be used to estimate the quality of the product when the actual product has not been or cannot be measured.

Therefore, sensors play a very important role in the semiconductor process. When any sensor fails, it will seriously affect the yield of the semiconductor process.

### SUMMARY

The disclosure is directed to an equipment sensing circuit board and an operation method thereof. At least one electronic fuse and at least one multiplexer are used. When a main sensor fails, a backup sensor can still be used to monitor the semiconductor equipment automatically and continuously.

According to one embodiment, an equipment sensing circuit board equipped on a semiconductor equipment is provided. The equipment sensing circuit board includes a main sensor, a backup sensor, a first electronic fuse, a second electronic fuse and a multiplexer. The main sensor is configured to monitor an operation of the semiconductor equipment for obtaining a main sensing signal. The backup sensor is configured to monitor the operation of the semiconductor equipment for obtaining a backup sensing signal. The first electronic fuse is disposed on the main sensor to output a first state signal. The second electronic fuse is disposed on the backup sensor to output a second state signal. The multiplexer is connected to the main sensor, the backup sensor, the first electronic fuse and the second electronic fuse. The multiplexer selects to output the main sensing signal or the backup sensing signal according to a combination of the first state signal and the second state signal.

According to another embodiment, an operation method of an equipment sensing circuit board is provided. The equipment sensing circuit board is disposed on a semiconductor equipment. The operation method of the equipment sensing circuit board includes the following steps. A main sensor monitors an operation of the semiconductor equipment to obtain a main sensing signal. A backup sensor monitors the operation of the semiconductor equipment to obtain a backup sensing signal. A first state signal of a first electronic fuse which is disposed on the main sensor is obtained. A second state signal of a second electronic fuse which is disposed on the backup sensor is obtained. A multiplexer selects to output the main sensing signal or the backup sensing signal according to a combination of the first state signal and the second state signal.

### BRIEF DESCRIPTION OF THE DRAWINGS

FIG. 1 shows a schematic diagram of an equipment monitoring system according to an embodiment.

FIG. 2 shows a schematic diagram of an equipment sensing circuit board according to an embodiment.

FIG. 3 shows a flowchart of an operation method of the equipment sensing circuit board according to an embodiment.

FIG. 4 shows a schematic diagram of an equipment sensing circuit board according to another embodiment.

FIG. 5 shows a flowchart of an operation method of the equipment sensing circuit board in FIG. 4 according to an embodiment.

FIG. 6 shows a schematic diagram of an equipment sensing circuit board according to another embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

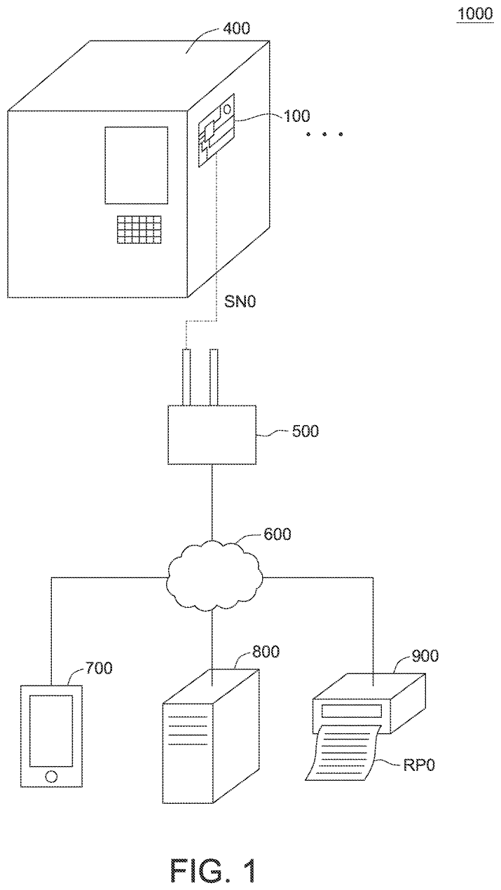

Please refer to FIG. 1, which shows a schematic diagram of an equipment monitoring system 1000 according to an embodiment. In the wafer manufacturing process, various semiconductor processes need to be carried out through several semiconductor equipment 400. The semiconductor equipment 400 can be equipped with an equipment sensing circuit board 100 to monitor the operation. A sensing signal SN0 is sent to the Internet 600 via a gateway 500 at the local network. Then, a server 800 can use the sensing signal SN0 for Prognostics and Health Management (PHM) or Virtual Metrology (VM). At the same time, the operator can also use a mobile device 700 to view the sensing signal SN0 in real time or use an output device 900 to obtain a statistic report RP0.

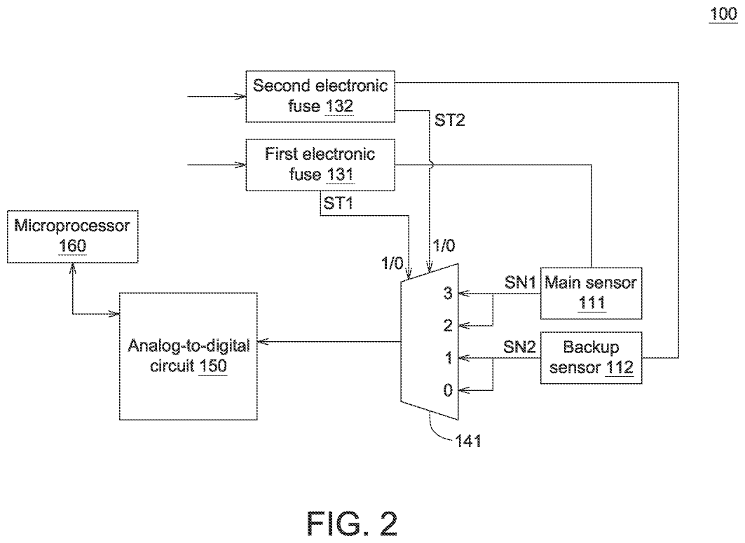

Please refer to FIG. 2, which shows a schematic diagram of the equipment sensing circuit board 100 according to an embodiment. The equipment sensing circuit board 100 includes a main sensor 111, a backup sensor 112, a first electronic fuse (first E-fuse) 131, a second electronic fuse (second E-fuse) 132, a multiplexer 141, an analog-to-digital circuit 150, and a microprocessor 160. The functions of the components are summarized as follows. The main sensor 111 is configured to monitor the operation of the semiconductor equipment 400 for obtaining a main sensing signal SN1. The backup sensor 112 is configured to monitor the operation of the semiconductor equipment 400 for obtaining a backup sensing signal SN2. The backup sensor 112 is configured to monitor the operation of the semiconductor equipment 400 for obtaining a backup sensing signal SN2. The main sensor 111 and the backup sensor 112 are identical. When the main sensor 111 fails, the backup sensor 112 can play a backup function, so that the monitoring of the semiconductor equipment 400 will not be interrupted.

The first electronic fuse 131 is equipped on the main sensor 111, and monitors the state of the main sensor 111 for obtaining a first state signal ST1. The second electronic fuse 132 is equipped on the backup sensor 112, and monitors the state of the backup sensor 112 for obtaining a second state signal ST2. The first state signal ST1 and the second state signal ST2 are continuously provided to the multiplexer 141.

The multiplexer 141 is connected to the main sensor 111, the backup sensor 112, the first electronic fuse 131, the second electronic fuse 132 and the analog-to-digital circuit 150. The multiplexer 141 selects to output the main sensing signal SN1 or the backup sensing signal SN2 according to the combination of the first state signal ST1 and the second state signal ST2.

For example, the multiplexer 141 is a 4-to-1 multiplexer. The multiplexer 141 has four input contacts numbered 0, 1, 2, 3, two control contacts and one output contact. The main sensor 111 is connected to the two input contacts numbered 2 and 3, and the backup sensor 112 is connected to the two input contacts numbered 0 and 1. The first electronic fuse 131 is connected to the control contact representing the second bit, and the second electronic fuse 132 is connected to the control contact representing the first bit. The output contact of multiplexer 141 is connected to analog-to-digital circuit 150.

When the main sensor 111 is in the normal state, the first state signal ST1 of the first electronic fuse 131 is at the high level, which can be regarded as the second bit value “1”; when the main sensor 111 is in the fault state, the first state signal ST1 of the first electronic fuse 131 is at the low level, which can be regarded as the second bit value “0.” When the backup sensor 112 is in the normal state, the second state signal ST2 of the second electronic fuse 132 is at the high level, which can be regarded as the first bit value “1”; when the backup sensor 112 is in the fault state, the second state signal ST2 of the second electronic fuse 132 is at the low level, which can be regarded as the value of the first bit “0.” The first state signal ST1 and the second state signal ST2 can be combined into four situations such as “11, 10, 01, 00.”

When the main sensor 111 is in the normal state and the backup sensor 112 is in the normal state, the first state signal ST1 and the second state signal ST2 can be combined into a “11” situation. At this time the multiplexer 141 selects the input contact numbered 3, so that the main sensing signal SN1 can be output from the output contact to the analog-to-digital circuit 150 and the microprocessor 160.

When the main sensor 111 is in the normal state and the backup sensor 112 is in the fault state, the first state signal ST1 and the second state signal ST2 can be combined into a “10” situation. At this time, the multiplexer 141 selects the input contact numbered 2, so that the main sensing signal SN1 can be output from the output contact to the analog-to-digital circuit 150 and the microprocessor 160.

When the main sensor 111 is in the fault state and the backup sensor 112 is in the normal state, the first state signal ST1 and the second state signal ST2 can be combined into a “01” situation. At this time, the multiplexer 141 selects the input contact numbered 1, so that the backup sensing signal SN2 can be output from the output contact to the analog-to-digital circuit 150 and the microprocessor 160.

Therefore, even if the main sensor 111 is in the fault state, the multiplexer 141 can continue to output the backup sensing signal SN2 to the analog-to-digital circuit 150 and the microprocessor 160.

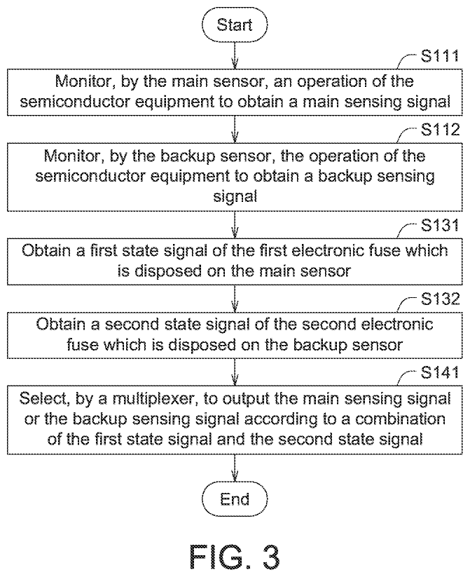

Please refer to FIG. 3, which shows a flowchart of the operation method of the equipment sensing circuit board 100 according to an embodiment. In step S111, the main sensor 111 monitors the operation of the semiconductor equipment 400 for obtaining the main sensing signal SN1. In step S112, the backup sensor 112 monitors the operation of the semiconductor equipment 400 for obtaining the backup sensing signal SN2. The step S111 and the step S112 can be performed continuously and simultaneously.

Then, in step S131, the first state signal ST1 of the first electronic fuse 131 is obtained. In step S132, the second state signal ST2 of the second electronic fuse 132 is obtained. The step S131 and the step S132 can be performed continuously and simultaneously.

Then, in step S141, the multiplexer 141 selects to output the main sensing signal SN1 or the backup sensing signal SN2 according to the combination of the first state signal ST1 and the second state signal ST2. The above steps S111, S112, S131, S132, S141 can be continuously executed simultaneously, as long as the main sensor 111 or the backup sensor 112 fails, the first state signal ST1 or the second state signal ST2 will be changed immediately, and the output selection will be changed accordingly.

Through the foregoing embodiment, when the main sensor 111 fails, the multiplexer 141 can automatically switch the input to the backup sensing signal SN2 of the backup sensor 112. Even if the operator needs a period of time to replace and repair the main sensor 111, it can still continue to monitor the semiconductor equipment 400 without seriously affecting the yield of the semiconductor process.

In addition to the sensor, the channel of the analog-to-digital circuit 150 may also be burned due to excessive voltage. In another embodiment, a channel backup mechanism of the analog-to-digital circuit 150 can be constructed.

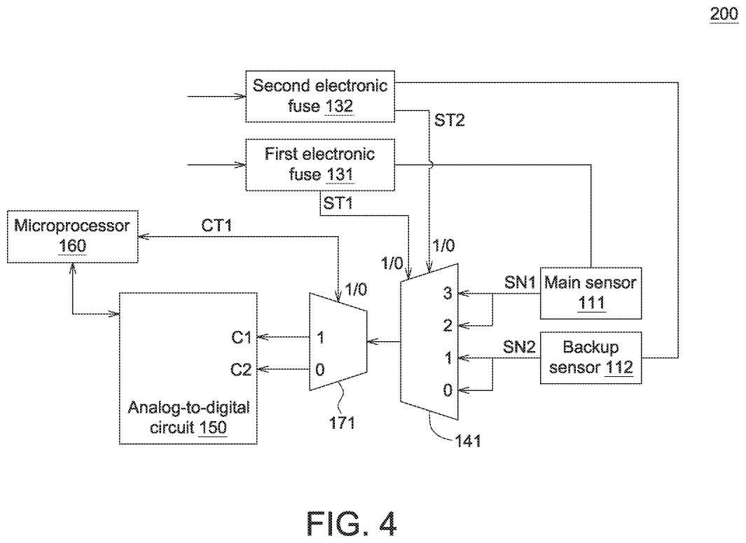

Please refer to FIG. 4, which shows a schematic diagram of an equipment sensing circuit board 200 according to another embodiment. The equipment sensing circuit board 200 includes the main sensor 111, the backup sensor 112, the first electronic fuse 131, the second electronic fuse 132, the multiplexer 141, the analog-to-digital circuit 150, the microprocessor 160 and a de-multiplexer 171. The de-multiplexer 171 is connected to the multiplexer 141, the analog-to-digital circuit 150 and the microprocessor 160. The de-multiplexer 171 is a 1-to-2 de-multiplexer. The de-multiplexer 171 has an input contact, a control contact and two output contacts numbered 0 and 1. The output contact of the multiplexer 141 is connected to the input contact of de-multiplexer 171. The microprocessor 160 is connected to the control contact representing the 1-bit of the de-multiplexer 171. The output contact numbered 1 of the de-multiplexer 171 is connected to a main channel C1 of the analog-to-digital circuit 150. The output contact numbered 0 of the de-multiplexer 171 is connected to a backup channel C2 of the analog-to-digital circuit 150.

In this embodiment, the microprocessor 160 can monitor the main channel C1 to obtain a channel status signal CT1. The channel status signal CT1 is inputted to the control contact of de-multiplexer 171. When the main channel C1 is in the normal state, the channel status signal CT1 is at the high level, which can be regarded as a 1-bit signal value “1”; when the main channel C1 is in the fault state, the channel status signal CT1 is at the low level, which can be regarded as a 1-bit signal value “0.”

When the main channel C1 is in the normal state, the channel status signal CT1 is “1.” The de-multiplexer 171 selects the output contact numbered “1”, so that the main sensing signal SN1 or the backup sensing signal SN2 can output from the output contact numbered “1” to the main channel C1 of the analog-to-digital circuit 150.

When the main channel C1 is in the fault state, the channel status signal CT1 is “0.” The de-multiplexer 171 selects the output contact numbered “0”, so that the main sensing signal SN1 or the backup sensing signal SN2 can output from the output contact numbered “0” to the backup channel C2 of the analog-to-digital circuit 150.

Therefore, even if the main channel 01 is in the fault state, the de-multiplexer 171 can continue to output one of the main sensing signal SN1 and the backup sensing signal SN2 to the analog-to-digital circuit 150 and the microprocessor 160.

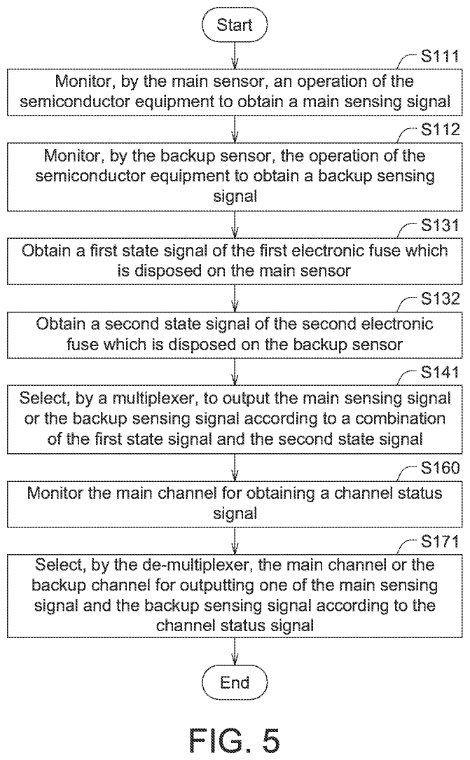

Please refer to FIG. 5, which shows a flowchart of an operation method of the equipment sensing circuit board 200 according to an embodiment. The flowchart in the FIG. 5 further includes step S160 and step S171. In step S160, the microprocessor 160 monitors the main channel C1 to obtain the channel status signal CT1. In step S171, the de-multiplexer 171 selects the main channel C1 or the backup channel C2 for outputting one of the main sensing signal SN1 and the backup sensing signal SN2 according to the channel status signal CT1. The above steps S160 and S171 can be continuously executed at the same time, as long as the main channel C1 fails, the channel status signal CT1 will be immediately changed, and then the backup channel C2 will be used.

Through the above embodiment, when the main channel C1 fails, the de-multiplexer 171 can automatically switch output to the backup channel C2 of the analog-to-digital circuit 150. Even if the operator has not performed the replacement and maintenance of the analog-to-digital circuit 150, the monitoring of the semiconductor equipment 400 can still be performed without seriously affecting the yield of the semiconductor process.

During the operation of the semiconductor equipment 400, the content that needs to be monitored includes temperature, pressure, gas concentration and other values. Therefore, the semiconductor equipment 400 may require multiple sensors and multiple channels. The following further describes embodiments of multiple sensors and multiple channels.

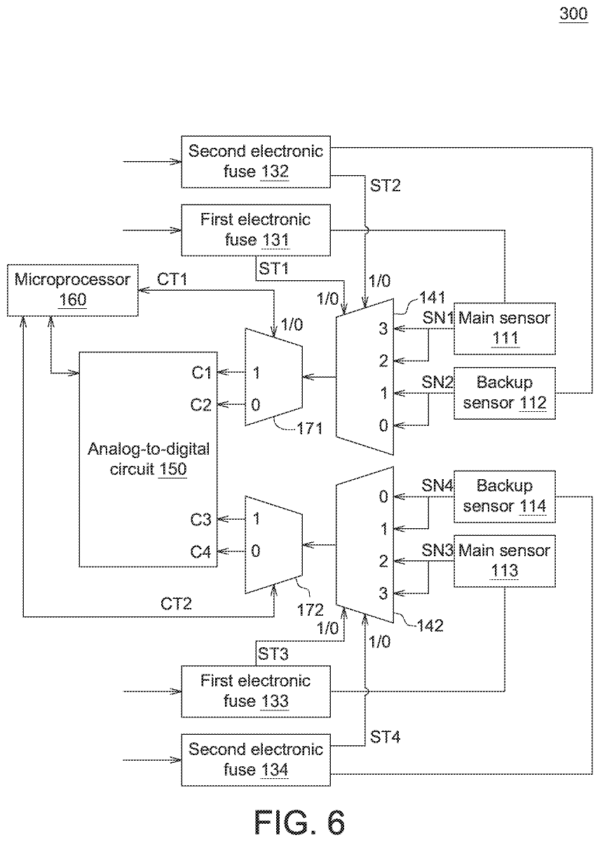

Please refer to FIG. 6, which shows a schematic diagram of an equipment sensing circuit board 300 according to another embodiment. The equipment sensing circuit board 300 includes the main sensor 111, the backup sensor 112, the main sensor 113, the backup sensor 114, the first electronic fuse 131, the second electronic fuse 132, the first electronic fuse 133, the second electronic fuse 134, the multiplexer 141, the multiplexer 142, the analog-to-digital circuit 150, the microprocessor 160, the de-multiplexer 171 and the de-multiplexer 172.

When the main sensor 113 is in the normal state and the backup sensor 114 is in the normal state, the first state signal ST3 and the second state signal ST4 can be combined into “11.” At this time, the multiplexer 142 selects the input contact numbered 3, so that the main sensing signal SN3 can be output from the output contact to the analog-to-digital circuit 150 and the microprocessor 160.

When the main sensor 113 is in the normal state and the backup sensor 114 is in the fault state, the first state signal ST3 and the second state signal ST4 can be combined into a “10.” At this time, the multiplexer 142 selects the input contact numbered 2, so that the main sensing signal SN3 can be output from the output contact to the analog-to-digital circuit 150 and the microprocessor 160.

When the main sensor 113 is in the fault state and the backup sensor 114 is in the normal state, the first state signal ST3 and the second state signal ST4 can be combined into a “01.” At this time, the multiplexer 142 selects the input contact numbered 1, so that the backup sensing signal SN4 can be output from the output contact to the analog-to-digital circuit 150 and the microprocessor 160.

Therefore, even if the main sensor 113 is in the fault state, the multiplexer 142 can continue to output the backup sensing signal SN4 to the analog-to-digital circuit 150 and the microprocessor 160.

When the main channel C3 is in the normal state and the channel status signal CT2 is “1”, the de-multiplexer 172 selects the output contact numbered “1”, so that the main sensing signal SN3 or the backup sensing signal SN4 can be outputted from the output contact numbered “1” to the main channel C3 of the analog-to-digital circuit 150.

When the main channel C3 is in the fault state and the channel status signal CT2 is “0”, the de-multiplexer 172 selects the output contact numbered “0”, so that the main sensing signal SN3 or the backup sensing signal SN4 can be outputted from the output contact numbered “0” to the backup channel C4 of the analog-to-digital circuit 150.

Therefore, even if the main channel C3 is in the fault state, the de-multiplexer 172 can continue to output one of the main sensing signal SN3 and the backup sensing signal SN4 to the analog-to-digital circuit 150 and the microprocessor 160.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An equipment sensing circuit board, equipped on a semiconductor equipment, wherein the equipment sensing circuit board comprises:
a main sensor, configured to monitor an operation of the semiconductor equipment for obtaining a main sensing signal;
a backup sensor, configured to monitor the operation of the semiconductor equipment for obtaining a backup sensing signal;
a first electronic fuse, disposed on the main sensor to output a first state signal;
a second electronic fuse, disposed on the backup sensor to output a second state signal; and
a multiplexer, connected to the main sensor, the backup sensor, the first electronic fuse and the second electronic fuse, wherein the multiplexer selects to output the main sensing signal or the backup sensing signal according to a combination of the first state signal and the second state signal.

2. The equipment sensing circuit board according to claim 1, wherein the main sensor is connected to two input ends of the multiplexer, and the backup sensor is connected to another two input ends of the multiplexer.

3. The equipment sensing circuit board according to claim 1, wherein the first state signal is a one bit signal, and the second state signal is a one bit signal.

4. The equipment sensing circuit board according to claim 1, wherein the main sensor and the backup sensor are identical.

5. The equipment sensing circuit board according to claim 1, wherein the first state signal and the second state signal are continuously provided to the multiplexer.

6. The equipment sensing circuit board according to claim 1, wherein the multiplexer is a 4-to-1 multiplexer.

7. The equipment sensing circuit board according to claim 1, further comprising:
an analog-to-digital circuit, having a main channel and a backup channel;
a microprocessor, configured to monitor the main channel for obtaining a channel status signal; and
a de-multiplexer, connected to the multiplexer, the analog-to-digital circuit and the microprocessor, wherein the de-multiplexer selects the main channel or the backup channel for outputting one of the main sensing signal and the backup sensing signal according to the channel status signal.

8. The equipment sensing circuit board according to claim 7, wherein the channel status signal is a one bit signal.

9. The equipment sensing circuit board according to claim 7, wherein the de-multiplexer is an 1-to-2 de-multiplexer.

10. An operation method of an equipment sensing circuit board, wherein the equipment sensing circuit board is disposed on a semiconductor equipment, and the operation method of the equipment sensing circuit board comprises:
monitoring, by a main sensor, an operation of the semiconductor equipment to obtain a main sensing signal;
monitoring, by a backup sensor, the operation of the semiconductor equipment to obtain a backup sensing signal;
obtaining a first state signal of a first electronic fuse which is disposed on the main sensor;
obtaining a second state signal of a second electronic fuse which is disposed on the backup sensor; and
selecting, by a multiplexer, to output the main sensing signal or the backup sensing signal according to a combination of the first state signal and the second state signal.

11. The operation method of the equipment sensing circuit board according to claim 10, wherein the main sensor is connected to two input ends of the multiplexer, and the backup sensor is connected to another two input ends of the multiplexer.

12. The operation method of the equipment sensing circuit board according to claim 10, wherein the first state signal is a one bit signal, and the second state signal is a one bit signal.

13. The operation method of the equipment sensing circuit board according to claim 10, wherein the main sensor and the backup sensor are identical.

14. The operation method of the equipment sensing circuit board according to claim 10, wherein the first state signal and the second state signal are continuously provided to the multiplexer.

15. The operation method of the equipment sensing circuit board according to claim 10, wherein the multiplexer is a 4-to-1 multiplexer.

16. The operation method of the equipment sensing circuit board according to claim 10, further comprising:
monitoring a main channel for obtaining a channel status signal; and
selecting, by a de-multiplexer, the main channel or the backup channel for outputting one of the main sensing signal and the backup sensing signal according to the channel status signal.

17. The operation method of the equipment sensing circuit board according to claim 16, wherein the channel status signal is a one bit signal.

18. The operation method of the equipment sensing circuit board according to claim 16, wherein the de-multiplexer is an 1-to-2 de-multiplexer.
